(19) United States
(12) Patent Application Publication
(10) Pub. No.: US 2010/0263712 A1
(43) Pub. Date: Oct. 21, 2010

(54) THREE TERMINAL MONOLITHIC MULTIJUNCTION SOLAR CELL

(76) Inventors: Michael Ludowise, San Jose, CA (US); Stephen J. Horne, El Granada, CA (US); Mark McDonald, Milpitas, CA (US)

Correspondence Address: BUCKLEY, MASCHOFF & TALWALKAR LLC, 50 LOCUST AVENUE, NEW CANAAN, CT, 06840, US

(21) Appl. No.: 12/424,658

(22) Filed: Apr. 16, 2009

(51) Int. Cl. H01L 31/042

(52) U.S. Cl. 136/249; 136/244

(57) ABSTRACT

A device and a method for its fabrication. The device may include a first surface, a second surface to receive light into the device, a first photovoltaic cell between the first surface and the second surface, and a second photovoltaic cell between the first surface and the second surface. The first photovoltaic cell includes a first region of a first photovoltaic material exhibiting an excess of a first type of charge carrier and a second region of the first photovoltaic material exhibiting an excess of a second type of charge carrier, and the second photovoltaic cell includes a first region of a second photovoltaic material exhibiting an excess of the first type of charge carrier and a second region of the second photovoltaic material exhibiting an excess of the second type of charge carrier.

A first contact is electrically connected to the second region of the first photovoltaic material, a second contact is electrically connected to the first region of the first photovoltaic material, and a third contact is electrically connected to the first region of the second photovoltaic material. The first surface is between at least a portion of the first contact and the second region of the first photovoltaic material, and the first surface is between at least a portion of the second contact and the second region of the first photovoltaic material.

### BACKGROUND

1. Field

Some embodiments generally relate to the conversion of sunlight to electric current. More specifically, embodiments may relate to improved photovoltaic cells for use in conjunction with solar collectors.

2. Brief Description

A solar cell includes photovoltaic material for generating charge carriers (i.e., holes and electrons) in response to received photons. The photovoltaic material includes a p-n junction which creates an electric field within the photovoltaic material. The electric field directs the generated charge through the photovoltaic material and to elements electrically coupled thereto. Many types of solar cells are known, which may differ from one another in terms of constituent materials, structure and/or fabrication methods. A solar cell may be selected for a particular application based on its efficiency, electrical characteristics, physical characteristics and/or cost.

A multijunction solar cell generally comprises one or more monojunction solar cells (i.e., a solar cell as described above) monolithically formed on one or more other monojunction solar cells. The photovoltaic material of each of the monojunction solar cells is associated with a different bandgap. Consequently, each monojunction solar cell of the multijunction solar cell absorbs (i.e., converts) photons from different portions of the solar spectrum.

The individual monojunction solar cells of a multijunction solar cell are connected in series. The voltage developed by the multijunction solar cell is therefore equal to the sum of the voltages across each of the monojunction solar cells. However, the current flowing through the multijunction solar cell is limited to the current produced by its lowest current-producing monojunction solar cell. The excess current produced by one or more of the other monojunction solar cells is dissipated as heat, thereby wasting the excess current and elevating the cell temperature. Increased cell temperature typically results in decreased cell efficiency.

Improved monolithic multijunction solar cells are desired.

### BRIEF DESCRIPTION OF THE DRAWINGS

The construction and usage of embodiments will become readily apparent from consideration of the following specification as illustrated in the accompanying drawings, in which like reference numerals designate like parts.

FIG. 1 is a schematic cross section of a device according to some embodiments.

FIG. 2 is a schematic diagram of a system according to some embodiments.

FIG. 3 is a cutaway plan view of a device according to some embodiments.

FIG. 4 is a schematic cross section of a device according to some embodiments.

FIG. 5 is a schematic cross section of a device according to some embodiments.

FIG. 6 is a schematic diagram of a system according to some embodiments.

FIG. 7 is a schematic cross section of a device according to some embodiments.

### DETAILED DESCRIPTION

The following description is provided to enable any person in the art to make and use the described embodiments and sets forth the best mode contemplated by for carrying out some embodiments. Various modifications, however, will remain readily apparent to those in the art.

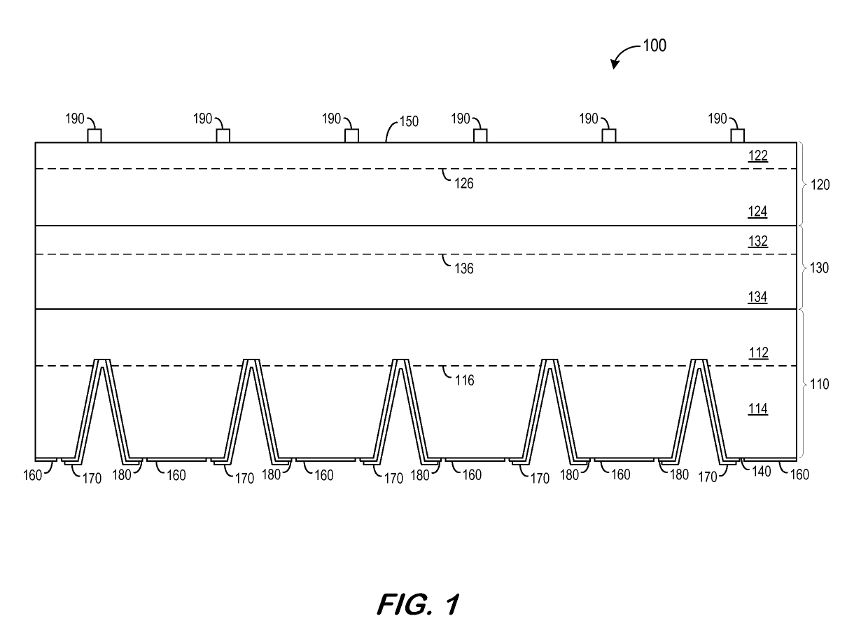

Device 100 of FIG. 1 is a monolithic multijunction photovoltaic cell according to some embodiments. Multijunction photovoltaic cell 100 includes photovoltaic cell 110 composed of a first photovoltaic material, photovoltaic cell 120 composed of a second photovoltaic material, and photovoltaic cell 130 composed of a third photovoltaic material. Each of cells 110 through 130 includes a region (112, 122 and 132) exhibiting an excess of a first type of charge carrier (e.g., electrons or holes) and a region (114, 124 and 134) exhibiting an excess of a second type of charge carrier (e.g., holes or electrons). These regions create respective p-n junctions within each of cells 110 through 130, specifically p-n junction 116 within photovoltaic cell 110, p-n junction 126 within photovoltaic cell 120, and p-n junction 136 within photovoltaic cell 130.

First surface 140 and second surface 150 are disposed on opposite sides of device 100. Each of cells 110 through 130 are disposed between first surface 140 and second surface 150. Second surface 150 is at least partially transparent. In this regard, photons of at least part of the sunlight spectrum may pass through second surface 150 and into device 100 during operation of device 100.

Contacts 160, 170 and 190 may be used to extract current from device 100 during operation. Each of contacts 160 is electrically connected to region 114 of cell 110. Each of contacts 170 is electrically connected to region 112 of cell 110, and electrically insulated from region 114 by virtue of dielectric insulator 180. At least a portion of each of contacts 160 and 170 is disposed on the “back” of device 100. More specifically, first surface 140 is between region 114 and at least a portion of each of contacts 160 and 170. Each of contacts 190 is electrically connected to region 122 of cell 120. Second surface 150 is between at least a portion of each of contacts 190 and region 122 of cell 120.

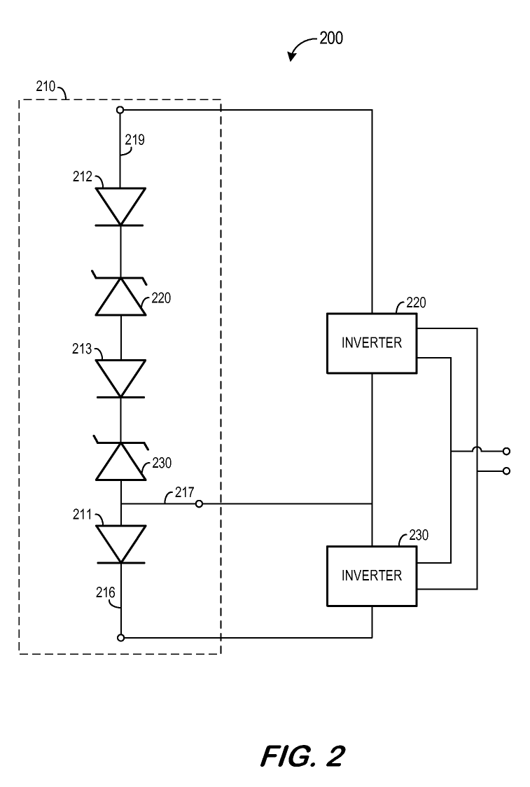

FIG. 2 is a schematic diagram of system 200 according to some embodiments. System 200 includes a schematic diagram of solar cell 210, which may be implemented by solar cell 100 of FIG. 1. In particular, diode 212 represents photovoltaic cell 120, diode 213 represents photovoltaic cell 130, and diode 211 represents photovoltaic cell 110. In the illustrated example, and according to conventional multijunction solar cell design, a first tunnel diode layer may be disposed between photovoltaic cell 120 and 130, and a second tunnel diode layer may be disposed between photovoltaic cell 130 and 110. These layers are represented by tunnel diodes 220 and 230, respectively. Although not shown in FIG. 1 or FIG. 2, solar cell 100 and solar cell 210 may include other active, dielectric, metallization and other layers and/or components that are or become known.

Terminals 216, 217 and 219 of solar cell 210 represent contacts 160, 170 and 190, respectively. Accordingly, the foregoing arrangement allows the extraction of current generated by photovoltaic cell 110 which exceeds the current generated by cells 120 and 130. Extraction of this excess current may increase an overall efficiency of device 100 and may lower an operating temperature of device 100 (also resulting in increased efficiency) with respect to prior arrangements. Embodiments are not limited to the arrangement of FIGS. 1 and/or 2.

An example of operation will now be provided. Each of the first, second and third photovoltaic materials is associated with a bandgap. The bandgap is an energy difference between the top of a material's valence band and the bottom of the material's conduction band. According to some embodiments, a bandgap associated with the first photovoltaic material of first photovoltaic cell 110 is less than a bandgap associated with the third photovoltaic material of third photovoltaic cell 130, and the bandgap associated with the third photovoltaic material of third photovoltaic cell 130 is less than a bandgap associated with the second photovoltaic material of second photovoltaic cell 120.

Surface 150 may receive light having any suitable intensity or spectra. Some photons of the received light are absorbed by second photovoltaic cell 120. For example, photons of the received light which exhibit energies greater than the bandgap associated with the second photovoltaic material enter second photovoltaic cell 120 and liberate holes in region 122 and electrons in region 124. The liberated electrons may be pulled into the region 122 and the liberated holes may be pulled into region 124 by means of an electric field established by and along p-n junction 126.

Photons of the received light which exhibit energies less than the bandgap associated with the second photovoltaic material may pass through photovoltaic cell 120 and into photovoltaic cell 130. Any of such photons which exhibit energies greater than the bandgap associated with the third photovoltaic material may liberate holes in region 132 and electrons in region 134. Again, the liberated electrons may be pulled into region 132 and the liberated holes may be pulled into region 134 by means of an electric field established by and along p-n junction 136.

The process may continue within photovoltaic cell 110 with respect to photons of the received light which exhibit energies less than the bandgaps associated with either the second photovoltaic material or the third photovoltaic material light 150. These photons which exhibit energies greater than the bandgap associated with the first photovoltaic material liberate holes in region 112 and electrons in region 114. The liberated electrons are pulled into region 112 and the liberated holes are pulled into region 114 of photovoltaic cell 110 by means of an electric field established by and along p-n junction 116.

As described in the present Background, photovoltaic cell 110 may generate more current than either of photovoltaic cells 120 or 130. Contact 170 provides an exit path for the excess current so it may be harvested as useful energy. In some embodiments, photovoltaic cell 110 is operated as a single-junction solar cell having external contacts 160 and 170, while photovoltaic cells 120 and 130 are operated as a series-connected pair of cells having external contacts 160 and 190.

System 200 illustrates one example of such operation. Inverter 220 is coupled to terminals 219 and 217 in a typical series-connected multijunction cell arrangement. Inverter 230 is coupled to terminals 217 and 216 in a typical single junction cell arrangement. In some embodiments, inverter 220 is designed to operate in conjunction with the particular voltages and currents provided by series-connected cells 212 and 213, and inverter 230 is designed to operate in conjunction with the particular voltages and currents provided by cells 211. Each of inverters 220 and 230 may be coupled in series or parallel to one or more other single or multijunction solar cells. The outputs of inverters 220 and 230 are connected to provide AC power to an external circuit.

A solar cell according to some embodiments may retain the spectral advantages of a conventional triple junction solar cell and may be fabricated using similar technologies. For example, various layers of solar cell 100 may be formed using molecular beam epitaxy and/or metal organic chemical vapor deposition. According to some embodiments, photovoltaic cell 110 is fabricated according to known techniques and the remaining photovoltaic cells are fabricated thereon. Each of photovoltaic cells 110 through 130 may include several layers of various photovoltaic compositions and dopings.

Any suitable materials that are or become known may be incorporated into device 100. For example, photovoltaic cell 110 may comprise Ge, GaAs, Si, or any other suitable substrate. Some examples of photovoltaic cell 130 include GaAs and GaInP, while examples of photovoltaic cell 120 include AlInP, GaInP and AlGaInP.

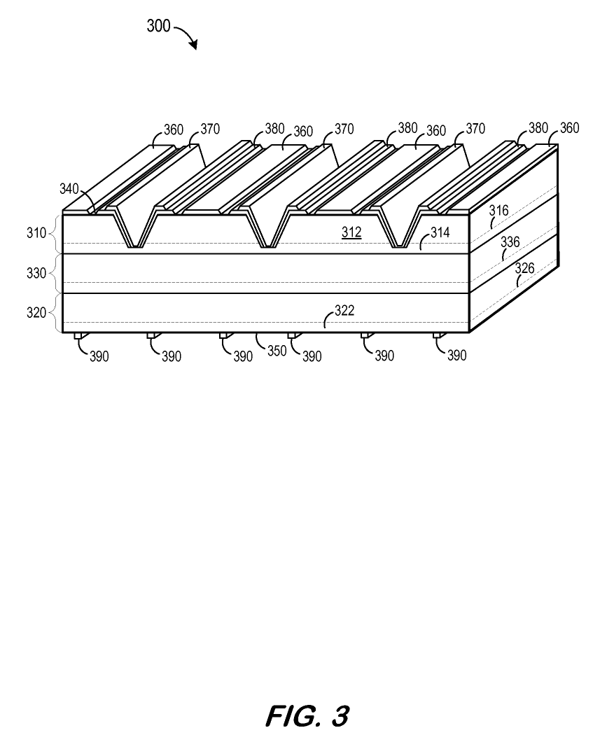

FIG. 3 is a cutaway plan view of solar cell 300 according to some embodiments. Solar cell 300 may comprise an implementation of solar cell 100 and/or solar cell 210 according to some embodiments. The elements and operation of cell 300 may be similar to those described above with respect to cell 100.

FIG. 3 illustrates a physical arrangement of contacts 360, contacts 370 and dielectric insulator 380 according to some embodiments. Contacts 360 are electrically connected to region 312 of photovoltaic cell 310, and contacts 370 are electrically connected to region 314 of photovoltaic cell 310. The sizes and shapes of contacts 360, contacts 370 and dielectric insulator 380, as well as the relative positions thereof, are not limited to that shown in FIG. 3. As non-exhaustive examples, contacts 370 and dielectric insulator 380 may exhibit a square or a circular cross section in a plane parallel to second surface 350.

Contacts 390 are electrically coupled to region 322 of photovoltaic cell 320. Contacts 390, in some embodiments, are disposed over second surface 350 in a grid-like pattern to facilitate suitable collection of generated electrons. Again, any contacts described herein may exhibit any size, pattern or arrangement.

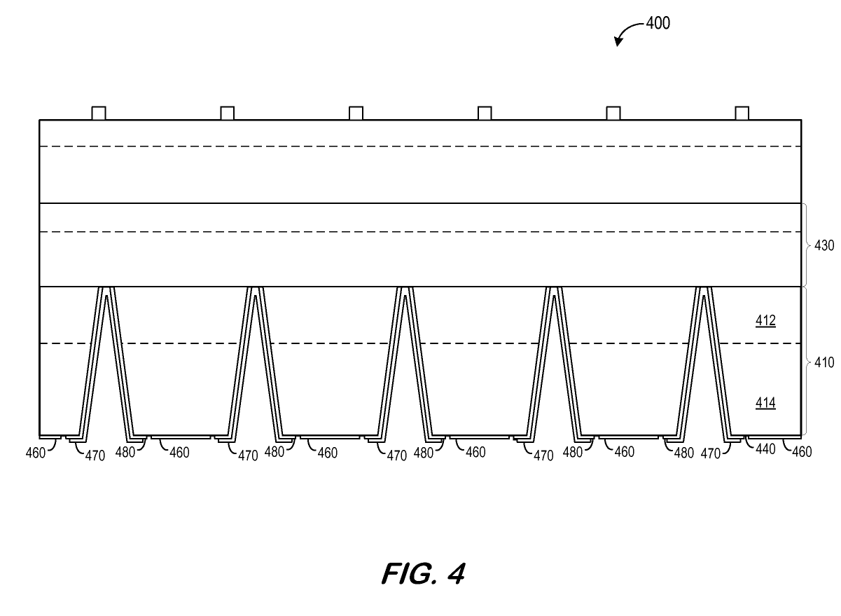

FIG. 4 is a schematic cross section of monolithic multijunction cell 400 according to some embodiments. The elements and operation of cell 400 may be similar to those described above with respect to cell 100. Moreover, cell 400 may embody cell 210 of FIG. 2.

Contacts 470 of cell 400 are electrically connected to region 412 of cell 410. However, in contrast to cell 100, contacts 470 extend to photovoltaic cell 430. Such an arrangement may facilitate fabrication of contacts 470 and dielectric insulator 480 in some embodiments. Contacts 470 may extend to any suitable degree through region 412 of cell 410.

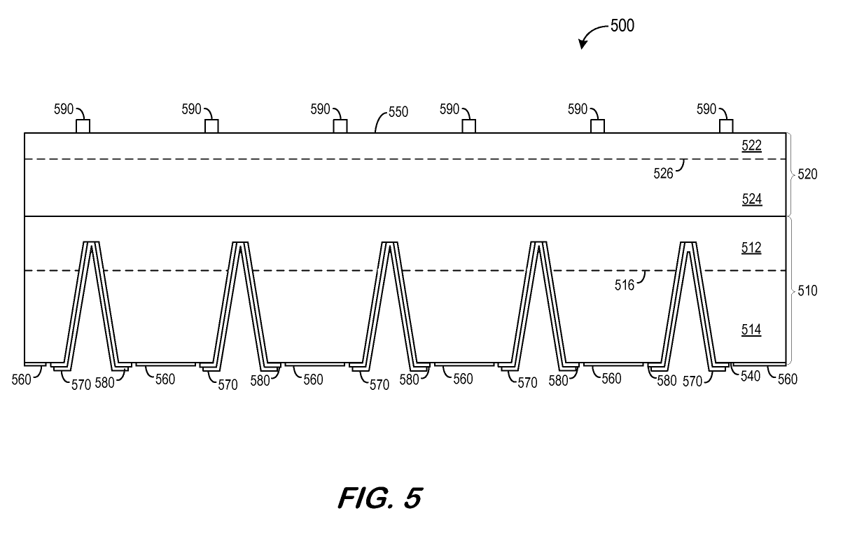

FIG. 5 depicts a schematic cross section of a monolithic multijunction photovoltaic cell according to some embodiments. Multijunction photovoltaic cell 500 includes photovoltaic cell 510 composed of a first photovoltaic material and photovoltaic cell 520 composed of a second photovoltaic material. The first and second photovoltaic materials may exhibit increasingly larger bandgaps for operation as described above.

Cells 510 and 520 include regions (512 and 522) exhibiting an excess of a first type of charge carrier (e.g., electrons or holes) and regions (514 and 524) exhibiting an excess of a second type of charge carrier (e.g., holes or electrons). These regions create respective p-n junction 516 within photovoltaic cell 510 and p-n junction 526 within photovoltaic cell 520.

Cells 510 and 520 are disposed between first surface 540 and second surface 550. Second surface 550 is at least partially transparent to accept light into cell 500 during operation.

Contacts 560 are electrically connected to region 514 of cell 510. Contacts 570 are electrically connected to region 512 of cell 510, and electrically insulated from region 514 by dielectric insulator 580. First surface 540 is between region 514 and at least a portion of each of contacts 560 and 570. Contacts 590 are electrically connected to region 522 of cell 520. Second surface 550 is between at least a portion of each of contacts 590 and region 520.

Cell 500 may be formed using molecular beam epitaxy, metal organic chemical vapor deposition, and/or other suitable techniques. According to some embodiments, photovoltaic cell 510 is initially fabricated and photovoltaic cell 520 is fabricated thereon. Contacts 560, 570 and 590 may be fabricated in any suitable order using any suitable process.

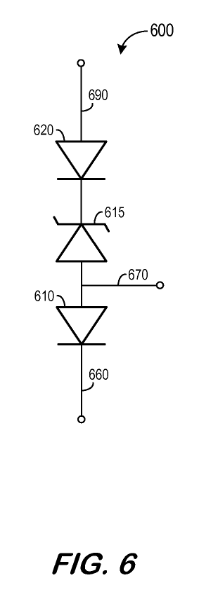

FIG. 6 is a schematic diagram of solar cell 600 according to some embodiments. Photovoltaic cell 500 of FIG. 5 may comprise one implementation of solar cell 600. In particular, diode 620 represents photovoltaic cell 520, and diode 610 represents photovoltaic cell 510. Tunnel diode 615 represents a tunnel diode (unshown) disposed between photovoltaic cells 520 and 510.

Terminals 660, 670 and 690 of solar cell 600 represent contacts 560, 570 and 590 of cell 500. Contacts 560, 570 and 590 therefore provide for extraction of current generated by photovoltaic cell 510 which exceeds the current generated by cell 520, or vice versa. Again, extraction of this excess current may increase an overall efficiency of device 500 and may lower an operating temperature of device 500.

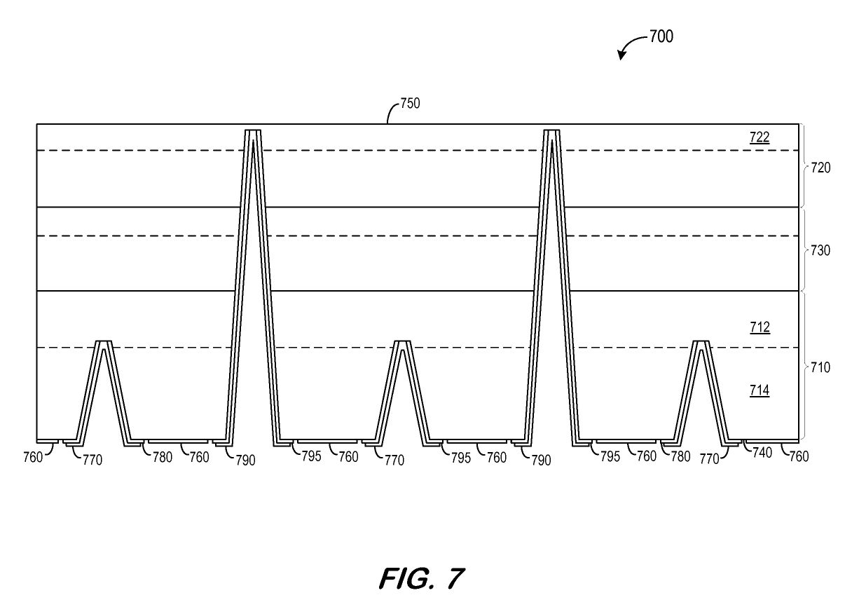

FIG. 7 is a schematic cross section of multijunction solar cell 700 according to some embodiments. Solar cell 700 includes photovoltaic cells 710 through 730 composed of respective photovoltaic materials to provide triple-junction operation as described above.

Similar to the foregoing arrangements, contacts 760 are electrically connected to region 714 of cell 710, and contacts 770 are electrically connected to region 712 and electrically insulated from region 714 by dielectric insulator 780. First surface 740 is between region 714 and at least a portion of each of contacts 760 and 770. Each of contacts 790 is electrically connected to region 722 of cell 720. Accordingly, solar cell 700 may be accurately represented by the schematic diagram of solar cell 210 of FIG. 2.

In contrast to the arrangements described above, first surface 740 is between at least a portion of each of contacts 790 and region 712 of cell 110. That is, at least a portion of each of contacts 760, 770 and 790 is disposed on the “back” of cell 700. As a result, front surface 750 is not obscured by contacts and is able to receive light over its entire area. Taken alone, this change may increase an overall efficiency of cell 700 in comparison to cell 100. However, this increase may be offset by a decrease in efficiency due to a decreased total volume of photovoltaic material. The actual decrease in total volume may be controlled based on a size, shape and number of contacts 770 and 790. Regardless of the effect on cell efficiency, the presence of all contacts on the back side of 700 may facilitate electrical connection thereof to external circuitry.

The several embodiments described herein are solely for the purpose of illustration. Embodiments may include any currently or hereafter-known versions of the elements described herein. Therefore, persons skilled in the art will recognize from this description that other embodiments may be practiced with various modifications and alterations.

What is claimed is:

1. A monolithic photovoltaic cell comprising:
a first surface;
a second surface to receive light into the photovoltaic cell;
a first photovoltaic cell between the first surface and the second surface, the first photovoltaic cell comprising a first region of a first photovoltaic material exhibiting an excess of a first type of charge carrier and a second region of the first photovoltaic material exhibiting an excess of a second type of charge carrier;
a second photovoltaic cell between the first surface and the second surface, the second photovoltaic cell comprising a first region of a second photovoltaic material exhibiting an excess of the first type of charge carrier and a second region of the second photovoltaic material exhibiting an excess of the second type of charge carrier;
a first contact electrically connected to the second region of the first photovoltaic material;
a second contact electrically connected to the first region of the first photovoltaic material; and
a third contact electrically connected to the first region of the second photovoltaic material,
wherein the first surface is between at least a portion of the first contact and the second region of the first photovoltaic material, and
wherein the first surface is between at least a portion of the second contact and the second region of the first photovoltaic material.

2. A cell according to claim 1,
wherein the first photovoltaic material is associated with a first bandgap,
wherein the second photovoltaic material is associated with a second bandgap greater than the first bandgap, and
wherein the second region of the second photovoltaic material is between the first region of the second photovoltaic material and the first region of the first photovoltaic material.

3. A cell according to claim 1,
wherein the second surface is between at least a portion of the third contact and the first region of the second photovoltaic material.

4. A cell according to claim 1,
wherein the first surface is between at least a portion of the third contact and the second region of the first photovoltaic material.

5. A cell according to claim 1, further comprising:
a third photovoltaic cell between the first photovoltaic cell and the second photovoltaic cell, the third photovoltaic cell comprising a first region of a third photovoltaic material exhibiting an excess of the first type of charge carrier and a second region of the third photovoltaic material exhibiting an excess of the second type of charge carrier.

6. A cell according to claim 5,
wherein the first photovoltaic material is associated with a first bandgap,
wherein the third photovoltaic material is associated with a third bandgap greater than the first bandgap,
wherein the second photovoltaic material is associated with a second bandgap greater than the third bandgap,
wherein the second region of the second photovoltaic material is between the first region of the second photovoltaic material and the first region of the third photovoltaic material, and
wherein the second region of the third photovoltaic material is between the first region of the third photovoltaic material and the first region of the first photovoltaic material.

7. A cell according to claim 5,
wherein the second surface is between at least a portion of the third contact and the first region of the second photovoltaic material.

8. A cell according to claim 5,
wherein the first surface is between at least a portion of the third contact and the second region of the first photovoltaic material.

9. A cell according to claim 5, further comprising:
a first inverter electrically connected to the first contact and to the second contact; and
a second inverter electrically connected to the second contact and to the third contact.

10. A cell according to claim 1, further comprising:
a first inverter electrically connected to the first contact and to the second contact; and
a second inverter electrically connected to the second contact and to the third contact.

11. A method comprising:
fabricating a first photovoltaic cell comprising a first region of a first photovoltaic material exhibiting an excess of a first type of charge carrier and a second region of the first photovoltaic material exhibiting an excess of a second type of charge carrier;
fabricating a second photovoltaic cell integral with the first photovoltaic cell, the second photovoltaic cell comprising a first region of a second photovoltaic material exhibiting an excess of the first type of charge carrier and a second region of the second photovoltaic material exhibiting an excess of the second type of charge carrier;
fabricating a first contact electrically connected to the second region of the first photovoltaic material;
fabricating a second contact electrically connected to the first region of the first photovoltaic material; and
fabricating a third contact electrically connected to the first region of the second photovoltaic material,
wherein the first surface is to receive light into the second photovoltaic cell and is between at least a portion of the first contact and the second region of the first photovoltaic material, and
wherein the first surface is between at least a portion of the second contact and the second region of the first photovoltaic material.

12. A method according to claim 11,
wherein the first photovoltaic material is associated with a first bandgap,
wherein the second photovoltaic material is associated with a second bandgap greater than the first bandgap, and
wherein the second region of the second photovoltaic material is between the first region of the second photovoltaic material and the first region of the first photovoltaic material.

13. A method according to claim 11,
wherein the second surface is between at least a portion of the third contact and the first region of the second photovoltaic material.

14. A method according to claim 11,
wherein the first surface is between at least a portion of the third contact and the second region of the first photovoltaic material.

15. A method according to claim 11, further comprising:
fabricating a third photovoltaic cell integral with the first photovoltaic cell and the second photovoltaic cell, the third photovoltaic cell comprising a first region of a third photovoltaic material exhibiting an excess of the first type of charge carrier and a second region of the third photovoltaic material exhibiting an excess of the second type of charge carrier.

16. A method according to claim 15,
wherein the first photovoltaic material is associated with a first bandgap,
wherein the third photovoltaic material is associated with a third bandgap greater than the first bandgap,
wherein the second photovoltaic material is associated with a second bandgap greater than the third bandgap,
wherein the second region of the second photovoltaic material is between the first region of the second photovoltaic material and the first region of the third photovoltaic material, and
wherein the second region of the third photovoltaic material is between the first region of the third photovoltaic material and the first region of the first photovoltaic material.

17. A method according to claim 15,
wherein the second surface is between at least a portion of the third contact and the first region of the second photovoltaic material.

18. A method according to claim 15,
wherein the first surface is between at least a portion of the third contact and the second region of the first photovoltaic material.

19. A method according to claim 15, further comprising:
electrically connecting a first inverter to the first contact and to the second contact; and
electrically connecting a second inverter to the second contact and to the third contact.

20. A method according to claim 11, further comprising:
electrically connecting a first inverter to the first contact and to the second contact; and
electrically connecting a second inverter to the second contact and to the third contact.
